(19) United States
(12) Patent Application Publication
(10) Pub. No.: US 2007/0090276 A1
(43) Pub. Date: Apr. 26, 2007

(54) Light detecting device

(76) Inventors: Jia Peng, Singapore (SG); Tiong Lim, Singapore (SG); Heng Giap Wong, Singapore (SG)

Correspondence Address: CARLTON FIELDS, PA, 1201 WEST PEACHTREE STREET, 3000 ONE ATLANTIC CENTER, ATLANTA, GA, 30309, US

(21) Appl. No.: 11/242,407

(22) Filed: Oct. 3, 2005

(51) Int. Cl. H01L 31/00

(52) U.S. Cl. 250/214.1

(57) ABSTRACT

The present invention is a light detecting device with compensation capacity. The light detecting device includes a light detector, a converter, a compensation circuit, a subtraction circuit, and an amplifier. The light detector can sense ambient light, generate a current signal indicative of the ambient light, and deliver the current signal to the converter. The converter can transform the current signal into a first voltage signal. The compensation circuit includes a shielded photodiode and a resistor and generates a suitable second voltage signal. The subtraction circuit can subtract the second voltage signal from the first voltage signal and produce a current signal that is solely dependent on the ambient light. The amplifier can amplify the current signal and produce a larger current signal to external loads.

### FIELD OF THE INVENTION

The present invention relates to light intensity detecting devices and in particular to a light detecting device with compensation capability.

### BACKGROUND OF THE INVENTION

In optical application systems, light detecting devices are usually used to sense ambient light such that optical signals can be converted into electrical signals. For the light detecting devices, sensitivity, bandwidth, and dynamic range typically are key operational parameters used to define their performance. The light detecting devices typically include a photodiode and other circuitry. When illuminated, the photodiode can detect ambient light as an optical signal and converts this optical signal into an electrical signal indicative of the ambient light. The other circuitry can further process the electrical signal to satisfy requirements from different applications.

In conventional applications, the photodiode is implemented with reverse biasing. In this situation, the receivers with a reverse biased photodiode have faster response. However, these light detecting devices may have some serious drawbacks, such as an increased leakage current, a larger dark current and higher noise levels. A larger reverse bias voltage used for reverse biasing the photodiode may also result in increased noise levels. Furthermore, excess noises resulting from signal processing can place a larger limit on the useful gain for the light detecting devices. In addition, the light detecting devices usually output a voltage signal at their output terminal that can adversely affect the dynamic range in various applications.

A rail to rail amplifier can be used to reverse bias the photodiode. However, the using of the rail to rail amplifier adds complexity to the design. Alternatively, a conventional amplifier can be applied to reverse bias the photodiode. However, this implementation requires a desirable reference voltage in the design, which can make the design more complicate. All of these constraints can add more complexity to circuit design that result in increase of the die area and power consumption.

FIG. 1 illustrates a block diagram of a prior art light detecting device 10 with dark current compensation utilizing reverse bias. The light detecting device 10 includes two photodiodes 11 and 11′, two transimpedance amplifiers 12 and 13, and a subtraction circuit 14. The light detecting device 10 can receive power from ambient light around the photodiodes 11 and 11′ and generate a voltage signal at its output terminal.

The photodiode 11 and the transimpedance amplifier 12 form a core stage. The transimpedance amplifier 12 includes a first amplifier and a feedback resistor. An anode of the photodiode 11 is coupled to a positive voltage, and a cathode of the photodiode 11 is coupled to an inverting terminal of the first amplifier. A non-inverting terminal of the first amplifier is coupled to ground through a resistor. As a result, reverse bias of the photodiode 11 is achieved. The photodiode 11 can generate a current signal composed of a photocurrent and a dark current. The feedback resistor in the transimpedance amplifier 12 is coupled between the inverting terminal and an output terminal of the first amplifier. The transimpedance amplifier 12 can convert the current signal from the photodiode 11 into a first voltage signal.

The photodiode 11′ and the transimpedance amplifier 13 duplicate the photodiode 11 and the amplifier 12 and act as a duplicate stage. The duplicate stage is placed at close proximity to the core stage so that the photodiodes 11 and 11′ are substantially in the same environment. Unlike the photodiode 11, the photodiode 11′ is shielded, i. e., the photodiode 11′ is not illuminated by the ambient light. As a result, only a duplicate dark current is generated by the photodiode 11′. The duplicate dark current can be converted into a second voltage signal by the transimpedance amplifier 13 in the same way as the transimpedance amplifier 12.

The subtraction circuit 14 can subtract the second voltage signal from the first voltage signal to eliminate the dark current components from the photodiodes 11 and 11′. Finally, the subtraction circuit 14 can output an output voltage signal to power to various loads. Therefore, the duplicate stage compensates the core stage by eliminating the dark current component. Since the exact duplicate stage is embedded in the light detecting device 10, more die area is required and additional circuitry of the duplicate stage also increases consumption of energy. Furthermore, the rail to rail design for the transamplifiers 12 and 13 adds more complexity for the light detecting device 10.

When the photodiode in the light detecting device is under reverse bias, the above-mentioned drawbacks and disadvantages can adversely affect the performance of the light detecting device. It is thus desirous to have an apparatus and method that compensates noises generated from the photodiode in a light detecting device with smaller die area, lower noises, and larger dynamic range, and it is to such apparatus and method the present invention is primarily directed.

### BRIEF SUMMARY OF THE INVENTION

In one embodiment, the invention is an apparatus for sensing ambient light. The apparatus includes a light detector, a converter with negative feedback, a compensation circuit, and a subtraction circuit. The apparatus further includes an amplifier. The light detector can generate a current when the ambient light has been detected. The converter is coupled to the light detector and converts the current into a first output signal. The compensation circuit is coupled to the light detector and the converter and generates a second output signal. The subtraction circuit is coupled to the converter and the compensation circuit. The subtraction circuit is capable of subtracting the second output signal from the first output signal and generating a third output signal. The third output signal is indicative of the ambient light. The amplifier can receive the third output signal, amplify the third output signal, and generate a current signal.

In another embodiment, the invention is an apparatus for sensing ambient light. The apparatus includes a light detector and a circuit with compensation capability. The light detector can detect the ambient light and produce a first current signal. The circuit is coupled to the light detector. The circuit is capable of processing the first current signal and generating a second current signal indicative of the ambient light.

In yet another embodiment, the invention is a method for reducing noises generated from a first photodiode. The method includes the steps for generating a first voltage signal reflecting ambient light, generating a second voltage signal from a second photodiode, subtracting the second voltage signal from the first voltage signal to reduce the noises, and producing a current signal through the subtracting. The first photodiode is zero biased. The second photodiode is shielded.

### BRIEF DESCRIPTION OF THE DRAWINGS

Advantages of the present invention will be apparent from the following detailed description of exemplary embodiments thereof, which description should be considered in conjunction with the accompanying drawings, in which:

FIG. 1 is a block diagram of a prior art light detecting device with compensation capacity through reverse bias;

FIG. 2 is a block diagram of an exemplary light detecting device with compensation capacity through zero bias according to the invention;

FIG. 3 is a diagram of an exemplary amplifier zero biasing a photodiode according to the invention;

FIG. 4A is a diagram of a converter according to one embodiment of the invention;

FIG. 4B is a diagram of an exemplary converter with dynamic offset cancellation utilizing chopper stabilization according to another embodiment of the invention;

FIG. 5A is a schematic diagram of a converter according to yet another embodiment of the invention;

FIG. 5B is a schematic diagram of an exemplary converter with dynamic offset cancellation utilizing autozeroing technique according to yet another embodiment of the invention;

FIG. 6 is a schematic diagram of a subtraction circuit of FIG. 2;

FIG. 7 is a schematic diagram of an amplifier of FIG. 2;

FIG. 8 is a schematic diagram of a voltage source of FIG. 2 according to one embodiment of the invention; and

FIG. 9 is a schematic diagram of an exemplary load coupled to the light detecting device of FIG. 2.

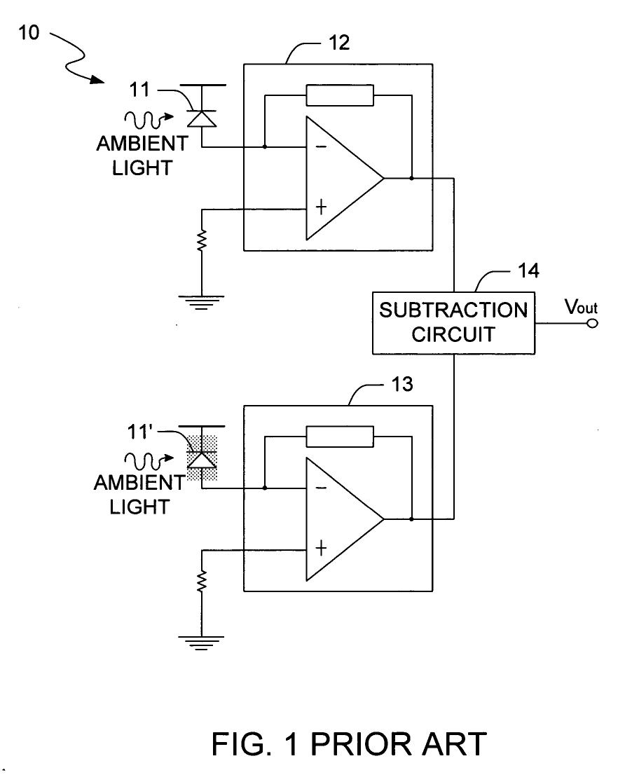

### DETAILED DESCRIPTION OF THE INVENTION

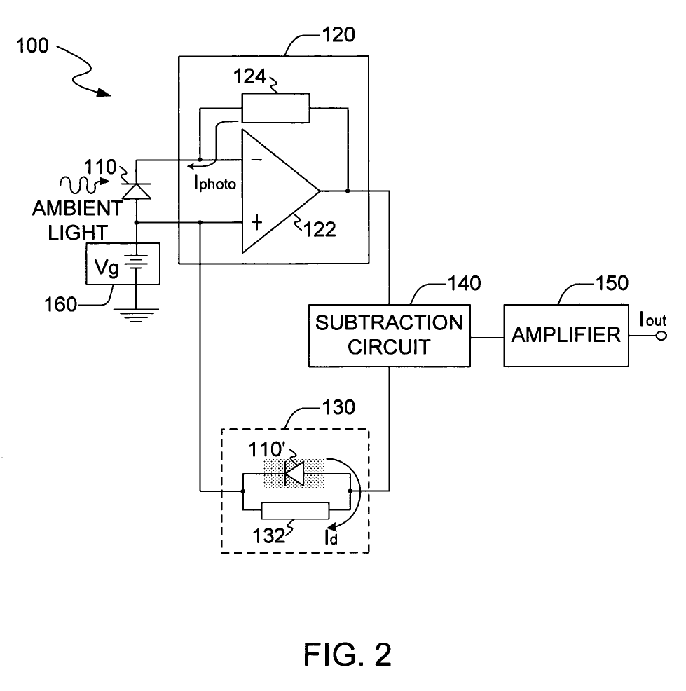

The invention provides a light detecting device with compensation capacity, in which a photodiode is zero biased, so that the light detecting device can effectively reduce noises resulting from signal processing. FIG. 2 illustrates a block diagram of an exemplary light detecting device 100 with compensation capacity. In this embodiment, the light detecting device 100 includes a light detector, for example, a photodiode 110, a converter 120, a compensation circuit 130, a subtraction circuit 140, an amplifier 150, and a voltage source 160. The light detecting device 100 is generally described as having two stages, a pre-amplifier stage and a post-amplifier stage. Typically, the pre-amplifier stage is defined as the first stage of amplification following the photodiode 110 that includes the converter 120, the compensation circuit 130, and the subtraction circuit 140. The post-amplifier stage is defined as the remaining stages of amplification required to further raise the electrical signal from the photodiode 110 to a level suitable for signal processing. In the light detecting device 100, the amplifier 150 is the post-amplifier stage.

The voltage source 160 is coupled to an anode of the photodiode 110 to provide power to the light detecting device 100. For example, Vg as shown acts as a reference voltage. When illuminated, the photodiode 110 can detect ambient light and generate a current indicative of the ambient light. The current is composed of a photocurrent and a dark current. In this situation, dark current noise caused by the dark current and other noises such as thermal noise, Johnson noise can be introduced by the photodiode 110.

The converter 120 can convert the current from the photodiode 110 into a voltage signal at its output terminal. In this embodiment, the converter 120 can include an amplifier 122 and a feedback circuit 124. The anode of the photodiode 110 is coupled to a non-inverting input terminal of the amplifier 122 while a cathode of the photodiode 110 is coupled to an inverting input terminal of the amplifier 122. The feedback circuit 124 is coupled between the inverting input terminal and the output terminal of the amplifier 122. The feedback circuit 124 can create a virtual short across the input terminals of the amplifier 122. In other words, the potential difference between the input terminals of the amplifier 122 is substantially zero. Therefore, the photodiode 110 is zero biased by the amplifier 122. Zero biasing the photodiode 110 can completely eliminate a leakage current that results from a potential difference across a junction of the photodiode 110. Zero biasing the photodiode 110 can minimize possible noises, such as the thermal noise and the Johnson noise generated from the photodiode 110. Additionally, the feedback circuit 124 can be used to improve the gain characteristic of the light detecting device 100. Therefore, the voltage signal at the output terminal of the amplifier 122 can include a useful voltage resulting from the photocurrent, the dark current noise caused by the dark current and other noises. The voltage signal from the amplifier 122 is a sum of the reference voltage Vg, the photocurrent component, the dark current component, and other noise component, in which the photocurrent component is defined as a signal resulting from the photocurrent, the dark current component is defined as a signal caused by the dark current, and the other noise component is defined as a signal converted from the other noises.

Though, the amplifier 122 and the feedback circuit 124 are illustrated in FIG. 2, those skilled in the art will appreciate that other combination of components can also be used to implement the conversion from the current signal into the voltage signal and zero biasing the light detector. The other configuration of the converter 120 will be described in greater detail below.

The compensation circuit 130 includes a photodiode 110′ that is shielded and an impedance element 132 coupled in parallel with the photodiode 110′. The compensation circuit 130 is coupled between the anode of the photodiode 110 and the subtraction circuit 140. The shielded photodiode 110′ is a duplicate of the photodiode 110. The shielded photodiode 110′ acting as a reference photodiode is placed at close proximity to the photodiode 110 (a core photodiode) such that both of the photodiodes 110 and 110′ are substantially in the same environment. Because the photodiode 110′ is shielded, only a dark current is generated and flows through the impedance element 132. A voltage across the impedance element 132 is given by equation (1). Therefore, the compensation circuit 130 can output a voltage signal that includes dark current noise and other noises to compensate the dark current noise and other noises generated by the photodiode 110. The voltage signal from the compensation circuit 130 is a sum of the reference voltage Vg, the dark current component, and other noise component.
V=R*Id (1)

where V is the voltage across the impedance element 132, R is an impedance of the impedance element 132, and the Id is the dark current generated by the shielded photodiode 110′.

The subtraction circuit 140 is coupled to the output terminal of the amplifier 122 and an anode of the shielded photodiode 110′. The subtraction circuit 140 can receive the voltage signal from the converter 120 and the voltage signal from the compensation circuit 130. At the subtraction circuit 140, the voltage signal from compensation circuit 130 is subtracted from the voltage signal from the converter 120. As a result, the dark current noises and other noises from the photodiode 110 can be greatly reduced. Finally, the subtraction circuit 140 can generate a current at its output terminal.

The amplifier 150 can amplify the current from the subtraction circuit 140 and generate a larger current at its output terminal to drive various external loads. A resistor having larger-scale impedance can be coupled to the output terminal of the amplifier 150 so that the larger current can be converted into a voltage signal. The voltage signal can vary as the resistance of the resistor coupled to the amplifier 150. Accordingly, a voltage in a larger scale can be generated by the amplifier 150 to supply power to the external loads. In other words, the light detecting device 100 has a higher dynamic swing. The amplifier 150 can further improve the gain characteristic of the light detecting device 100.

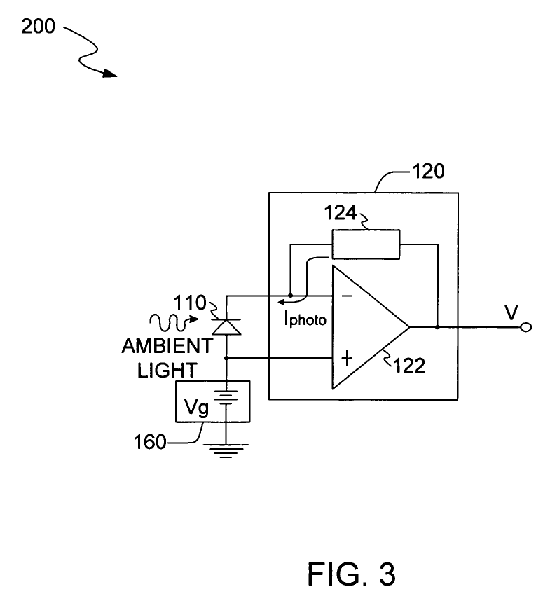

Turning to FIG. 3, a diagram 200 of an exemplary amplifier zero biasing a photodiode is illustrated. In this embodiment, the voltage source 160 provides the reference voltage, Vg, to the photodiode 110 and the converter 122. The converter 122 with the negative feedback path can create a virtual short between the inverting input terminal and the non-inverting input terminal of the amplifier 122. Therefore, the voltages at these two input terminal of the amplifier 122 are equal, i.e., a potential difference across the anode and the cathode of the photodiode 110 is substantially equal to zero. Accordingly, zero biasing the photodiode 110 is implemented.

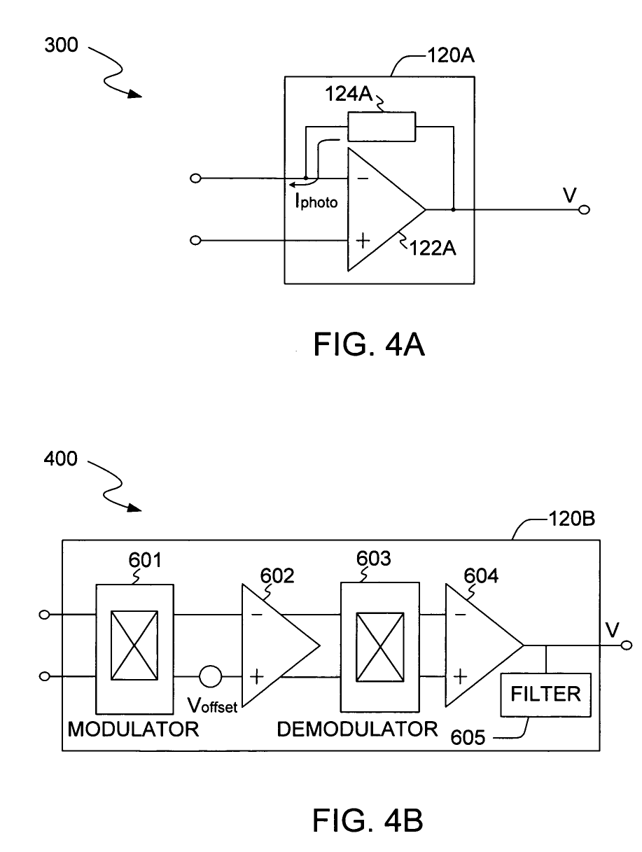

FIG. 4A illustrates a block diagram of one embodiment 300 of the converter 120 in FIG. 2 in accordance with the invention. In this embodiment 300, the converter 120A includes a transimpedance amplifier 122A and a resistive feedback network 124A. The resistive feedback network 124A is couple between the inverting input terminal and the output terminal of the transimpedance amplifier 122A as the negative feedback path. The resistive feedback network 124A can be implemented through various configurations, for example, a resistor. Those skilled in the art will appreciate that other combination of components with resistive characteristics can be used herein as the negative feedback path without departing the spirit of the present invention.

FIG. 4B illustrates a block diagram of another embodiment 400 of a converter 120B. The converter 120B can utilize chopper stabilization technique to implement dynamic offset cancellation. The converter 120B includes a modulator 601, an amplifier 602, a demodulator 603, an amplifier 604, and a filter 605.

The modulator 601 is coupled between the anode and the cathode of the photodiode 110 in FIG. 2. The modulator 601 can modulate the DC signal, such as the photocurrent and the dark current, from the photodiode 110 into an AC signal. The modulator 601 can then transmit the AC signal to the inputs terminal of the amplifier 602. In IC (integrated circuit) design, a smaller signal, i.e., an offset (Voffset), usually exists between the input terminals of the amplifier 602. The AC signal from the modulator 601 and the offset can be amplified by the amplifier 602, and then be demodulated by the demodulator 603. As a result, the demodulator 603 can output an AC signal related to the offset in higher frequency, and a DC signal related to the DC signal from the photodiode 110. The amplifier 604 can further amplify the AC signal and the DC signal from the demodulator 603 and then transmit these signals at its output terminal. Since the AC signal related to the offset is at higher frequency, it can be filtered by a low-pass filter, for example, the filter 605.

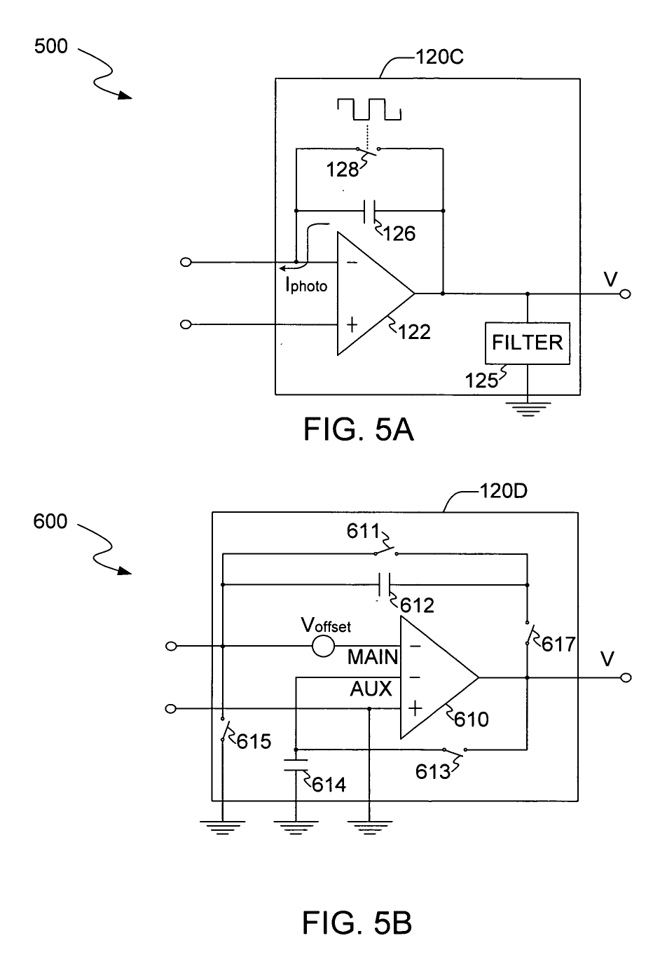

FIG. 5A presents a schematic diagram of another embodiment 500 of the converter 120 in FIG. 2. In this embodiment, the converter 120C includes the amplifier 122, a filter 125, a capacitor 126, and a switch 128. The converter 120C acts as a switching integrator. The capacitor 126 and the switch 128 form the negative feedback path. The switch 128 can operate between an open state and a close state under control of a clock signal. Under the open state, the switch 128 may be turned on for a specific time interval. When the switch 128 operates in the open state, the integrating capacitor 126 is reset. However, under the close state, the switch 128 may be turned off for another specific time interval, and the integrating capacitor 126 can be charged by the amplifier 122. Consequently, a saw-tooth waveform will be generated at the output terminal of the amplifier 122. The saw-tooth waveform is further filtered by a low-pass filter 125 so that an average voltage signal is sent out at the output terminal of the amplifier 122.

Although only one switch and one capacitor are illustrated in FIG. 5A, the number of the switch and the capacitor is not limited herein. Those skilled in the art will appreciate that any number of the switch and the capacitor can be used herein for the converter 120 in FIG. 2 without departing the spirit of the invention.

FIG. 5B is a schematic diagram of another embodiment of 600 of the converter 120 in FIG. 2. In this embodiment, the converter 120D can utilize autozeroing technique to remove the offset (Voffset). The converter 120D includes an amplifier 610, four switches 601, 603, 605 and 607, and two capacitors 602 and 604. The converter 120D acts as a switch integrator.

In the converter 120D, the amplifier 610 has a main inverting input terminal, au auxiliary inverting input terminal, a non-inverting input terminal, and an output terminal. The switch 601 is coupled between the main inverting input terminal of the amplifier 610 and the switch 607. The capacitor 602 is coupled in parallel with the switch 601. The switch 603 is coupled between the auxiliary inverting input terminal and the output terminal of the amplifier 610. The capacitor 604 is coupled between the auxiliary inverting input terminal of the amplifier 610 and the ground. The switch 605 is coupled between the main inverting input terminal of the amplifier 610 and the ground. The non-inverting input terminal of the amplifier 610 is directly coupled to the ground.

The main inverting input terminal and the non-inverting input terminal of the amplifier 610 act as two input terminals of the converter 120D receives the current, such as the photocurrent and the dark current, from the photodiode 110. The converter 120D operating as the switch integrator has an autozero phase, a proceeding integrating phase, and a reset phase. During the autozero phase, the switches 601, 603 and 605 are close while the switch 607 is open. As a result, the main inverting input terminal is equivalent to being connect to the ground so that the amplifier 610 is a unity feedback configuration with the auxiliary input terminal. Consequently, the offset of the amplifier 610 is sampled and then stored at the capacitor 604. During the proceeding phase, the switches 601, 603, and 605 are open while the switch 607 is close. The current from the photodiode 110 is then integrated at the output terminal of the amplifier 610. During the reset phase, the switch 601 is close to reset the charges across the capacitor 602. Accordingly, autozeroing technique is employed to reduce the low frequency noise, e.g., the offset, to improve performance of the pre-amplifier stage.

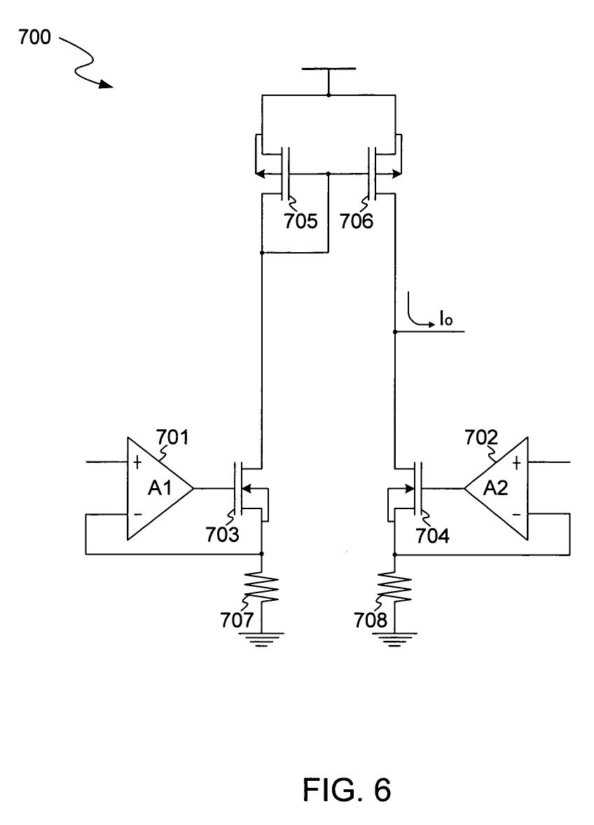

FIG. 6 illustrates a schematic diagram 700 of the subtraction circuit 140 in FIG. 2. In the schematic diagram 700, the subtraction circuit 140 consists of two amplifiers 701 and 702, two PMOS transistors 703 and 704, two resistors 708 and 709, and a current mirror. The current mirror includes two NMOS transistors 705 and 706. The amplifier 701 receives the voltage signal from the converter 120 in FIG. 2 that consists of the reference voltage, the photocurrent component, the dark current component, and other noise component. Similarly, the amplifier 702 can receive the voltage signal from the compensation circuit 130 in FIG. 2 which is composed of the reference voltage, the dark current component, and other noise component.

The amplifier 701, the PMOS transistor 703, and the resistor 707 can form a voltage follower. Hence, a voltage equal to the voltage signal from the converter 120 will be replicated to the resistor 707. As a result, a current dependent on the voltage signal from the converter 120 can flow through the NMOS transistor 705. In other words, the voltage signal from the converter 120 is converted into the current flowing through the NMOS transistor 705. In the same way, a current based on the voltage signal from the compensation circuit 130 can flow through the NMOS transistor 706. For the current mirror, the subtraction of these two currents can result in a net current (Io). Since the reference voltage component, the dark current component and other noise component are removed through the subtraction, the net current is assertively determined only by the photocurrent component. Consequently, the reference voltage from the voltage source 160 and noises resulting from, for example, the dark current, the temperature can effectively be isolated from the useful signal, the photocurrent.

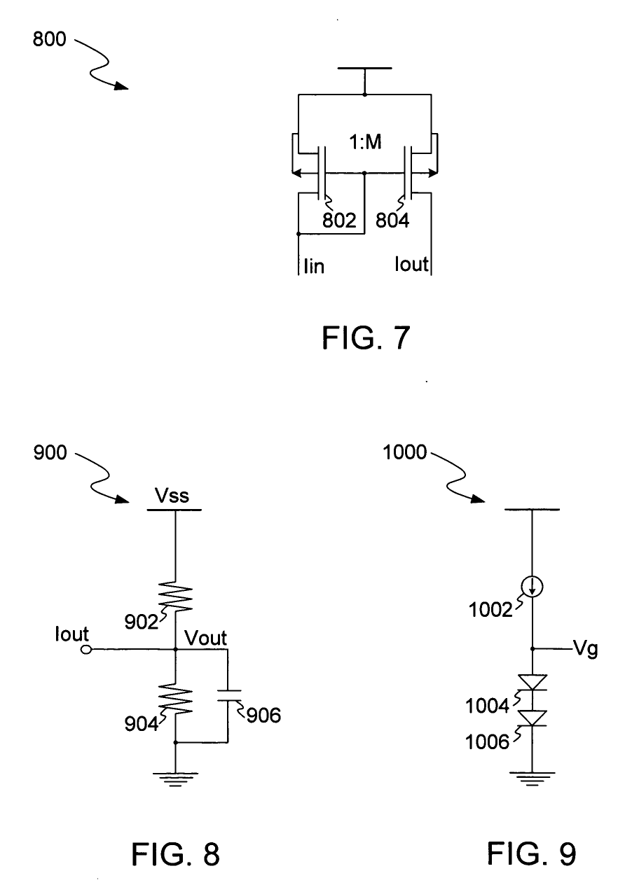

FIG. 7 is a schematic diagram of one embodiment of the amplifier 150 in FIG. 2. In the embodiment 800, the amplifier 150 is composed of a current mirror that includes two NMOS transistors 802 and 804. The current Iin is the net current Io in FIG. 6. The current Iin is mirrored by the NMOS transistor 804 and is amplified with a desirable multiplier ratio, for example, M. In other words, the amplifier 150 can operate in a current mode. The current Iin flowing through the NOMS transistor 802 will create a voltage at a gate terminal of the NMOS transistors 802 and 804. The voltage at the gate terminal of the NMOS transistors 802 and 804 is a square root of a drain current of the NMOS transistor 802 that is determined by the current Iin. Hence, the amplifier 150 can achieve lower voltage headroom in the current mode. Furthermore, the amplifier 150 can improve the gain characteristic of the light detecting device 100 so that the pre-amplifier stage and the post-amplifier stage can effectively be avoided to enter into a saturation region. Therefore, the amplifier 150 can sent out a current Iout at a source terminal of the NMOS transistor 804.

FIG. 8 is a schematic diagram of an exemplary load coupled to the light detecting device 100 in FIG. 2. In one embodiment 900, the load consists of two resistors 902 and 904, and a capacitor 906. The resistor 904 is coupled in series with the resistor 902, and in parallel with the capacitor 906. The resistors 902 and 904 acts as a resistive divider to scale down an output voltage whose value is given by equation (2). Since the output voltage is determined by the resistance of the resistor 904, the output voltage can have a higher dynamic swing.

$$Vout = \frac{R 904}{R 904 + R 902} Vss + Iout * R 904 \qquad ( 2 )$$

FIG. 9 is a schematic diagram of one embodiment 1000 of the voltage source 160 in FIG. 2. In this embodiment, the voltage source 160 is composed of a current source 1002 and two diodes 1004 and 1006. Because the reference voltage Vg can be removed by the subtraction circuit 140, it is unnecessary to implement an exact voltage in the integrated circuit design. Hence, the two diodes 1004 and 1006 can be coupled in series and be forward biased to generate the reference voltage Vg.

In operation, when illuminated by the ambient light and zero biased by a converter 120, a photodiode 110 can convert the optical signal into the electrical signal (the current signal) that consists of the photocurrent related to the light intensity of the ambient light and the dark current. Additionally, other noises resulting from the temperature and other factors can also be introduced by the photodiode 110.

The converter 120 can receive the reference voltage from the voltage source 160 and the current signal from the photodiode 110. The current signal includes the photocurrent component, the dark current component and other noise component. The converter 120 can transform the current signal into a voltage signal which also includes the above-mentioned three components. The converter 120 can deliver a voltage signal including the reference voltage component, the photodiode component, the dark current component, and the other noise component at its output terminal. Furthermore, the converter 120 may be equipped with a negative feedback path to improve its gain characteristic.

In order to compensate the reference voltage component, the dark current component and other noise component, a compensation circuit 130 is provided to perform the compensation capability. The compensation circuit 130 can include a duplicate photodiode 110′ that is shielded. Because of being shielded, the photodiode 110′ can only generate the dark current. In order to convert the dark current into a voltage signal, a resistor 132 is provided herein. As described above, the shielded photodiode 110′ is placed close to the photodiode 110, thus other noise component can also be produced. Consequently, the compensation circuit 130 can output the voltage signal including a reference voltage component, a dark current component, and other noise component. The dark current component is equal to the dark current multiplied by the resistance of the resistor 132. The suitable resistance of the resistor 132 is selected so that the dark current component from the compensation circuit 130 is equal to that from the converter 120.

A subtraction circuit 140 can receive the voltage signals from the converter 120 and the compensation circuit 130. Through the subtraction at the subtraction circuit 140, the reference voltage component, the dark current component and other noise component can be completely neutralized. Therefore, only the photocurrent component will remain after the subtraction. The subtraction circuit 140 can output a current signal reflective of the photocurrent. Therefore, the current signal is transferred from the pre-amplifier stage to the post-amplifier stage for further signal processing.

In the post-amplifier stage, an amplifier 150 is provided to further amplify the current signal received from the subtraction circuit 140. The amplifier 150 generates an amplified current to the external load. The amplifier current can be easily converted into a voltage through a resistive divider so that the dynamic swing of the light detecting device 100 is greatly extended. Additionally, the amplifier 150 can further improve the gain characteristic of the light detecting device 100. The pre-amplifier stage and the post-amplifier stage can advantageously prevent each of the amplifiers in the light detecting device 100 from entering into the saturation region.

The embodiments that have been described herein, however, are but some of the several which utilize this invention and are set forth here by way of illustration but not of limitation. It is obvious that many other embodiments, which will be readily apparent to those skilled in the art, may be made without departing materially from the spirit and scope of the invention as defined in the appended claims. Furthermore, although elements of the invention may be described or claimed in the singular, the plural is contemplated unless limitation to the singular is explicitly stated.

1. (canceled)

2. (canceled)

3. (canceled)

4. (canceled)

5. (canceled)

6. (canceled)

7. (canceled)

8. (canceled)

9. (canceled)

10. (canceled)

11. (canceled)

12. (canceled)

13. (canceled)

14. (canceled)

15. An apparatus for sensing ambient light, the apparatus comprising:
a light detector for detecting the ambient light, the light detector producing a first current signal; and
a circuit with compensation capability, the circuit being coupled to the light detector, the circuit capable of processing the first current signal and generating a second current signal indicative of the ambient light.

16. The apparatus of claim 15, wherein the light detector is a photodiode.

17. The apparatus of claim 15, wherein a potential across the light detector is substantially zero.

18. The apparatus of claim 15, wherein the first current signal generated by the light detector further including a photocurrent and a dark current, the photocurrent current signal reflecting the ambient light.

19. The apparatus of claim 15, wherein the circuit further comprising:
a converter with negative feedback, the converter being coupled to the light detector and converting the first current signal into a first output signal;
a compensation circuit coupled to the light detector and the converter, the compensation circuit generating a second output signal;
a subtraction circuit coupled to the converter and the compensation circuit, the subtraction circuit being capable of subtracting the second output signal from the first output signal and generating a third output signal, wherein the third output signal indicative of the ambient light; and
an amplifier coupled to the subtraction circuit, the amplifier being capable of receiving the third output signal, amplifying the third output signal, and generating the second current signal.

20. The apparatus of claim 19, wherein the converter further comprising an amplifier and a feedback circuit, the resistor divider acting as a negative feedback path being coupled between an inverting terminal and an output terminal of the amplifier.

21. The apparatus of claim 19, wherein the converter further comprising a modulator, an amplifier and a demodulator coupled in series.

22. The apparatus of claim 19, wherein the converter further comprising an amplifier, a switch, a capacitor, and a filter, the switch being coupled in parallel with the capacitor and coupled between an inverting terminal and an output terminal of the amplifier, and the output terminal of the amplifier being coupled to the filter.

23. The apparatus of claim 19, wherein the converter further comprising an amplifier, a first switch, a second switch, a third switch, a fourth switch, a first capacitor, and a second capacitor, the amplifier having a main inverting input terminal, an auxiliary inverting input terminal, and an output terminal, wherein the first switch being coupled between the main inverting input terminal of the amplifier and the ground, the second switch being coupled between the main inverting input terminal and the third switch, the third switch being coupled between the second switch and the output terminal of the amplifier, and the fourth switch being coupled between the auxiliary inverting input terminal and the output terminal of the amplifier, wherein the first capacitor being coupled between the main inverting input terminal and the third switch, and the second capacitor being coupled between the auxiliary inverting input terminal and the ground.

24. The apparatus of claim 19, wherein the compensation circuit further comprising a duplicate light detector and a resistor couple in parallel, the duplicate light detector being shielded and producing a dark current, and wherein the second output signal generated by the compensation circuit having a value, the value being determined by the dark current and the resistor.

25. The apparatus of claim 19, wherein the subtraction circuit further comprising two voltage followers and a current mirror to reduce noises generated from the light detector, each of the two voltage follower being coupled to the current mirror.

26. The apparatus of claim 19, wherein the amplifier further comprising a current mirror.

27. (canceled)

28. (canceled)

29. (canceled)

30. (canceled)

31. (canceled)
